(19) United States
(12) Patent Application Publication
(10) Pub. No.: US 2025/0370421 A1
(43) Pub. Date: Dec. 4, 2025

(54) Centralized Artificial Intelligence Engine for a Fleet of Process Chambers in Semiconductor Manufacturing

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/679,384

(22) Filed: May 30, 2024

(51) Int. Cl. G05B 19/042; G05B 23/02; H01L 21/67

(52) U.S. Cl. CPC G05B 19/0426; G05B 23/0254; H01L 21/67167; H01L 21/67276; G05B 2219/45031

(57) ABSTRACT

This invention introduces a centralized artificial intelligence (AI) engine for semiconductor manufacturing, autonomously managing multiple process chambers. It dynamically allocates resources, enabling autonomous recipe generation and real-time adjustments. Subsystem controllers convert these recipes into time series control signals, optimizing latency. Incorporating digital twins, the system significantly improves efficiency, reduces costs, and enhances adaptability, offering a sophisticated solution for autonomous process control in semiconductor manufacturing.

### FIELD OF INVENTION

This invention pertains to the field of semiconductor manufacturing, more specifically to systems and methods for optimizing the control and management of semiconductor process chambers using a centralized artificial intelligence (AI) engine.

### BACKGROUND

The semiconductor manufacturing industry is characterized by its high complexity, requiring precise control over various process parameters to ensure the quality and efficiency of semiconductor devices. Traditionally, managing the operations of multiple process chambers has been challenging due to the need for individualized control systems, leading to increased costs and complexity in process optimization. Furthermore, the advent of big data and AI technologies presents an opportunity to enhance operational efficiency and adaptability in semiconductor manufacturing. However, effectively integrating these technologies to manage a fleet of process chambers remains a significant challenge. Existing systems often lack the capability to dynamically allocate resources, adjust process recipes in real time, and analyze performance trends across similar subsystems, thereby failing to fully leverage the potential of AI in optimizing semiconductor manufacturing processes.

### SUMMARY

According to one embodiment of the present invention, a process system is provided that incorporates a centralized artificial intelligence (AI) engine for overseeing and controlling operations across multiple process chambers. This centralized AI engine establishes direct connections to subsystems or parts within either a single tool or across multiple tools, thereby centralizing control mechanisms. The architecture enables the centralized AI engine to act as a shared resource across process systems, each with multiple chambers, which significantly enhances operational efficiency. It dynamically adjusts the resources allocated to each chamber based on real-time workload, effectively reducing overall operational costs while employing a more potent computing infrastructure equipped with AI capabilities.

In another embodiment, the invention features an autonomous process recipe generator within the centralized AI engine. This generator autonomously crafts and adjusts process recipes in real-time, ensuring ongoing optimization of the semiconductor manufacturing process by adapting to changes in process conditions or wafer characteristics without manual oversight.

Additionally, subsystem analyzers are included within the centralized AI engine framework. These analyzers track performance across fleets of identical subsystems, facilitating the early detection of trend deviations, drifts, or anomalies. Identifying such discrepancies allows for preemptive process adjustments, thereby maintaining optimal operational conditions and enhancing overall yield.

The invention also leverages a digital twin, more specifically, a compute-efficient digital twin, to simulate the semiconductor manufacturing environment's physical and chemical processes. This virtual modeling, typically based on neural networks and trained with synthetic data derived from multi-physics models, provides a resource-efficient avenue for testing and refining process recipes before their real-world application.

A further aspect of the invention involves generating operating instructions from the autonomously created process recipes for specific subsystems. The centralized AI engine is responsible for converting the generated process recipes into detailed operating instructions tailored to the requirements of the subsystems associated with the selected process chamber. Subsystem controllers then receive these operating instructions and convert them into time series control signals for the subsystem parts. By meticulously adjusting the starting times of these control signals, the system minimizes latency, thereby optimizing the responsiveness and efficiency of the process chamber operations.

Through these embodiments, the invention articulates a comprehensive approach to semiconductor manufacturing, integrating AI, digital twinning, and real-time analytics to foster a system that is not only more efficient and cost-effective but also highly adaptable to the evolving demands of semiconductor production processes.

### BRIEF DESCRIPTIONS OF DRAWINGS

To enhance understanding, the following descriptions reference the accompanying drawings:

FIG. 1A: Illustrates a conventional process system employing a dedicated controller for each process chamber.

FIG. 1B: Presents a schematic diagram of an exemplary process system utilizing a centralized artificial intelligence (AI) engine, featuring a single process tool composed of multiple process chambers.

FIG. 1C: Depicts the subsystems of a process chamber directly connected to a centralized AI engine.

FIG. 2: Exhibits a schematic diagram of an exemplary process system that employs a centralized AI engine, incorporating multiple process tools, each consisting of multiple process chambers.

FIG. 3A: Illustrates an embodiment wherein a centralized AI engine is connected to subsystem controllers.

FIG. 3B: Outlines a flowchart for transforming a process recipe into time series control signals for actuators of the subsystem parts.

FIG. 4: Showcases an embodiment in which a centralized AI engine is directly connected to parts of the subsystems.

FIG. 5A: Illustrates an embodiment of a communication system employing optical fibers to connect the centralized AI engine with the subsystem.

FIG. 5B: Displays an embodiment of a centralized AI engine based on GPU and HBM.

FIG. 6: Reveals another embodiment of a centralized AI engine incorporating a digital twin of a process chamber.

FIG. 7A: Presents another embodiment of the centralized AI engine utilizing virtual process chamber controllers.

FIG. 7B: Offers a flowchart illustrating the process of dynamically allocating resources to virtual process chamber controllers based on their workload.

FIG. 8: Illustrates another embodiment of the communication system employing wireless communication links.

FIG. 9: Depicts another embodiment of the communication system utilizing dedicated or shared EtherCAT.

FIG. 10: Showcases an embodiment of the communication system employing mixed communication links.

FIG. 11: Schematically depicts an example of a centralized AI engine that includes a training core.

FIG. 12: Provides a flowchart detailing the autonomous generation of a process recipe.

FIG. 13: Exhibits a flowchart describing the process of autonomously adjusting a process recipe during a processing event.

FIG. 14: Displays a flowchart outlining the process of constructing an inference core based on data generated by a chamber digital twin.

FIG. 15: Shows a flowchart detailing an alternative method for autonomously generating a process recipe through reinforced learning.

### DETAILED DESCRIPTIONS

This section delves into the specific embodiments of the present invention, aiming to provide a comprehensive understanding. It is important to note that while certain implementations are described to illustrate the inventive aspects clearly, any alterations and modifications that fall within the scope of the appended claims are intended to be encompassed by this disclosure. These detailed descriptions underscore the innovative features of the invention, setting it apart from existing technologies.

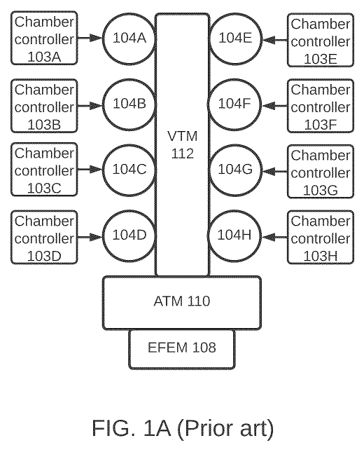

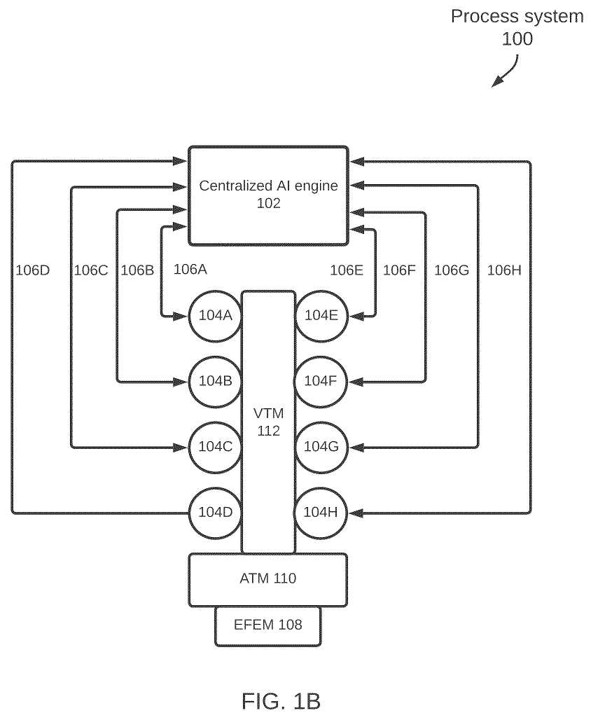

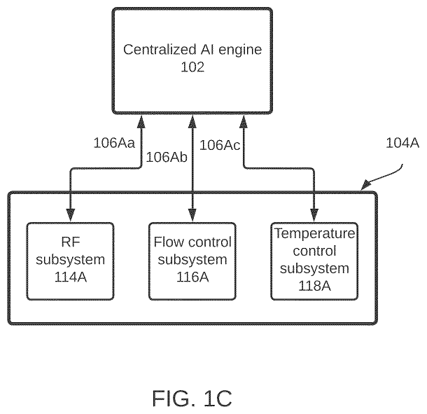

FIG. 1A delineates a conventional process system wherein multiple process chambers are interconnected to a singular platform, with eight process chambers exemplified. This platform encompasses an equipment front end module (EFEM), labeled as 108, an atmosphere transfer module (ATM), labeled as 110, and a vacuum transfer module (VTM), labeled as 112. The platform's design facilitates the reception of an incoming wafer, its transfer into a process chamber via one or more robots, and the subsequent retraction of the wafer following the completion of a predefined process recipe. A hallmark of this conventional system is the independent control exerted over each process chamber (104A to 104H) by dedicated chamber controllers (103A to 103H), as depicted in FIG. 1A. These controllers are tasked with the execution of the process recipe.

As the complexity of wafer processing has surged, the volume of data produced and gathered by various sensors within a process chamber has expanded exponentially. While the advent of “big data” and AI presents a promising avenue to enhance the efficiency of process chambers and reduce operational costs, this potential remains untapped due to the absence of a process system architecture capable of effectively leveraging this data. For instance, AI-driven controllers necessitate the use of sizable neural networks, which are optimized by parallel computing via GPUs. However, equipping each process chamber with a dedicated AI engine would exacerbate cost concerns in semiconductor manufacturing.

Against this backdrop, a novel process system, as illustrated in FIG. 1B, is introduced. This exemplary process system 100 mirrors the conventional setup with multiple process chambers (104A to 104H) attached to a platform. However, it diverges by integrating a centralized AI engine 102 that serves all process chambers collectively, as showcased in FIG. 1B. This architecture not only facilitates the use of a more potent controller but also distributes its elevated cost across numerous process chambers. Although eight process chambers are exemplified in FIG. 1B, the centralized AI engine is scalable, capable of servicing an extensive array of process chambers across various tools or platforms. A potential challenge in this architecture is the communication bottleneck that could emerge as the number of process chambers escalates. To mitigate this, each process chamber (104A to 104H) is linked to the centralized AI engine via a distinct communication link (106A to 106H), ensuring independent and parallel communication. The centralized AI engine 102 might embody a tensor core GPU architecture, such as NVIDIA's H100, renowned for its parallel computing prowess. This setup allows for the creation of virtual process chamber controllers that utilize centralized resources efficiently, offering each process chamber the perception of having a dedicated controller through high-bandwidth, dedicated communication links.

FIG. 1C illustrates a scenario where a vacuum plasma chamber is directly connected to the centralized AI engine. The process chamber 104A comprises a radio frequency (RF) subsystem 114A, a flow control subsystem 116A, and a temperature control subsystem 118A, each directly linked to the centralized AI engine 102 via individual communication links (106Aa, 106Ab, and 106Ac). In one configuration, the communication link 106A integrates multiple channels, each dedicated to a specific subsystem, potentially utilizing optical communication technologies like wavelength division multiplexing (WDM), with the choice between dense wavelength division multiplexing (DWDM) or coarse wavelength division multiplexing (CWDM) being dictated by the data demands of applications.

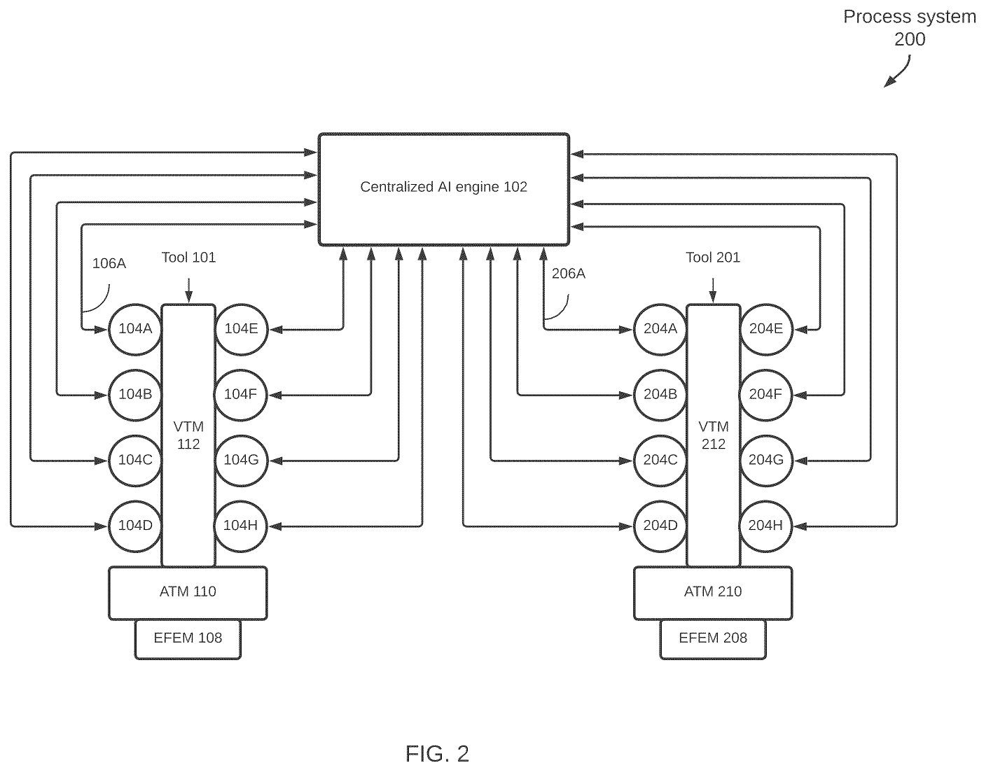

FIG. 2 schematically demonstrates the application of the centralized AI engine 102 in managing operations across multiple chambers situated in various tools or platforms. Specifically, it exemplifies the centralized AI engine's connection to a first set of eight chambers (104A to 104H) within tool 101 and to a second set of eight chambers (204A to 204H) within tool 201 Each chamber is linked to the centralized AI engine 102 via communication links, 106A to 106H for tool 101 and 206A to 206H for tool 201, respectively. Communication links 106A and 206A are labelled exemplarily in the FIG. 2 for the simplicity. Like the configuration depicted in FIG. 1C, these communication links may also support independent channels for direct connections between subsystems or parts and the centralized AI engine 102. The deployment of the centralized AI engine extends beyond controlling just two tools; it is adaptable to manage an assortment of tools, each possibly housing a varying number of chambers. Moreover, the tools interconnected with the centralized AI engine 102 can encompass diverse types, incorporating different chamber technologies. This inventive concept is designed to be inclusive of a wide range of tools utilized in semiconductor manufacturing, encompassing, but not limited to, etching, deposition, lithography, ion implantation, cleaning, chemical-mechanical polishing, thermal processing, metrology, and bevel etching/deposition processes. Furthermore, its application is not confined to wafer fabrication alone but also extends to packaging processes involving wafers, dies, interposers, and substrates.

The chamber-to-platform configuration illustrated in FIGS. 1B and 2 serves as an example. The industry recognizes that tool arrangements can vary significantly, accommodating different tool types. Additionally, chamber operations may either involve a vacuum environment or not, with all such variations falling within the purview of this invention.

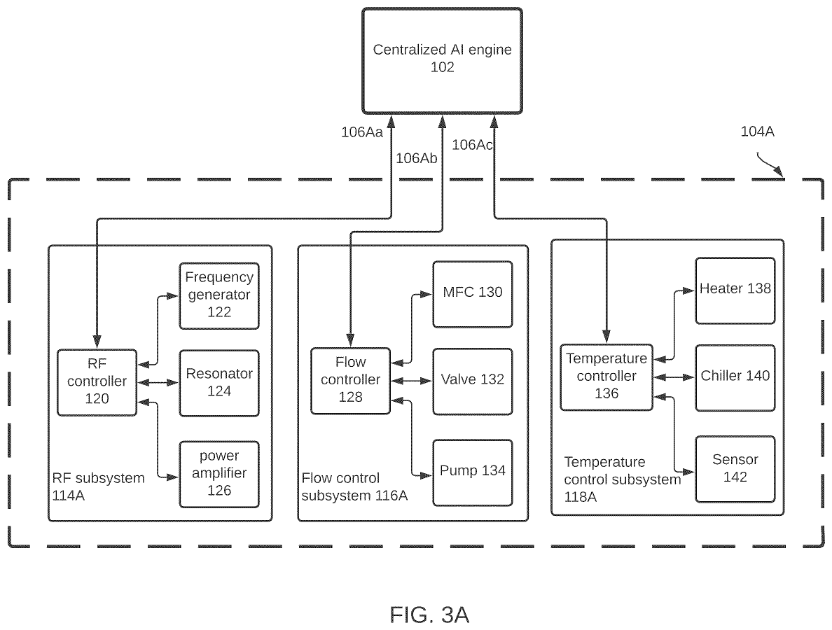

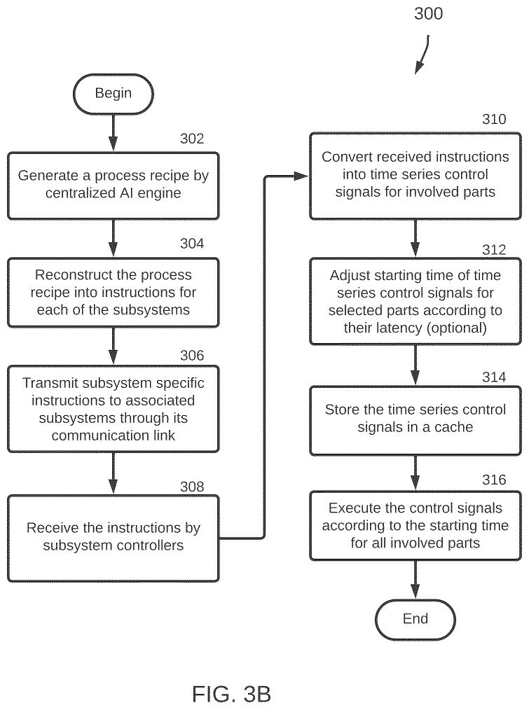

FIG. 3A introduces an implementation where local controllers facilitate communication between subsystem components and the centralized AI engine 102.
For an RF subsystem 114A, an RF controller 120 manages operations of a frequency generator 122, a resonator 124, and a power amplifier 126, although it is acknowledged that the subsystem might include additional parts as known in the art. The RF controller 120, upon receiving operational instructions from the centralized AI engine 102 via communication link 106Aa, translates these directives into time-series control signals for the parts of the subsystems.
The flow control subsystem 116A utilizes a flow controller 128 to oversee operations of a mass flow controller (MFC) 130, a valve 132, and a pump 134. This listing is illustrative, with the possibility of incorporating multiple parts within each category for practical applications. Common additions, such as a manometer for vacuum chamber pressure measurement, are anticipated. The flow controller 128, upon receipt of operational instructions from the centralized AI engine 102 via communication link 106Ab, converts these directives into time-series control signals for the subsystem parts.
A temperature controller 136 is deployed within a temperature control subsystem 118A to manage the operations of a heater 138, a chiller 140, and a temperature sensor 142. This subsystem, too, may include additional components as commonly known. The temperature controller 136, receiving operational instructions from the centralized AI engine 102 via communication link 106Ac, translates these into time-series control signals for the subsystem parts.

In certain implementations, these time-series control signals are cached, potentially utilizing static random-access memory (SRAM) for expedited operation. The actuators of the various components execute the control signals in accordance with predetermined execution times.

Execution latency can vary significantly across different subsystem actuators. For instance, mechanical movements typically require more time than electrical signal activations. In some configurations, the initiation times for certain actuators are adjustable by the subsystem controllers to minimize overall latency.

A flowchart presented in FIG. 3B outlines a generalized methodology for transforming a process recipe into time series control signals applicable to various components within different subsystems. The process, designated as 300, initiates with step 302, where the centralized AI engine 102 autonomously generates a process recipe. Following this, in step 304, the process recipe is deconstructed into instruction sets tailored for each subsystem, with each set corresponding to a particular subsystem. These instructions are designed as time series. Subsequently, in step 306, these instruction sets are simultaneously dispatched to the respective subsystems via their dedicated communication links. Upon receipt by the subsystem controllers in step 308, the instructions undergo conversion into time series control signals for the implicated parts in step 310. Given the variance in latency across subsystems when executing control signals, the process's speed is constrained by the slowest part. To address this, step 312 introduces a strategy to recalibrate the initiation times based on the latencies of the involved components, potentially advancing the start times for slower components to enhance the overall step speed. The refined time series control signals are then cached in step 314, with their execution scheduled according to the adjusted start times in step 316.

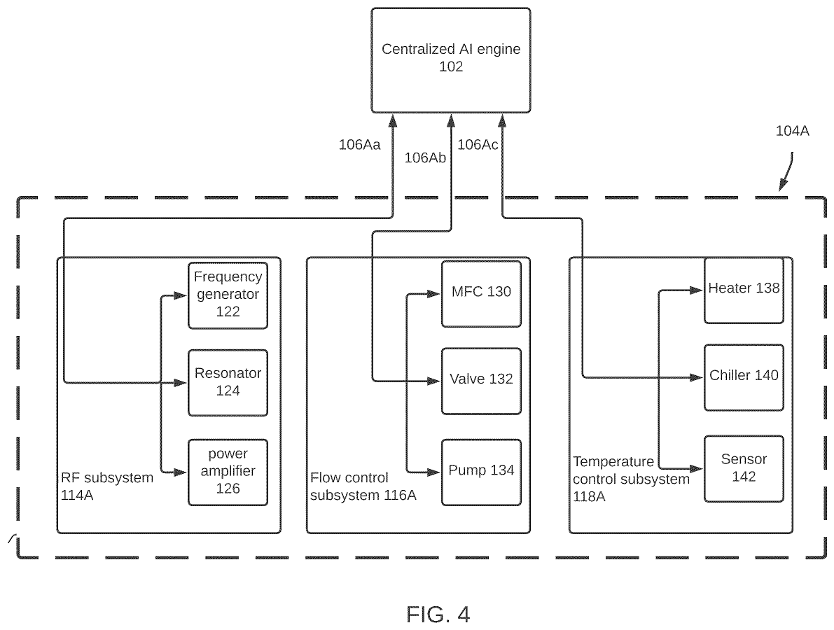

FIG. 4 unveils an alternative embodiment of the process system that forgoes local controllers for subsystems. In this configuration, the centralized AI engine 102 establishes direct connections to the parts, assuming the role of controller for the subsystems. This setup simplifies the subsystem design, though it necessitates careful management of communication latencies between the centralized AI engine 102 and the various subsystem components to prevent bottlenecks.

Additional variations include utilizing subsystem controllers for selected subsystems while the centralized AI engine oversees the remainder, amalgamating several subsystems under a single controller, and allocating processing functions to the centralized AI engine with caching capabilities embedded within the subsystems. All these adaptations are encompassed within the scope of the inventive concept presented.

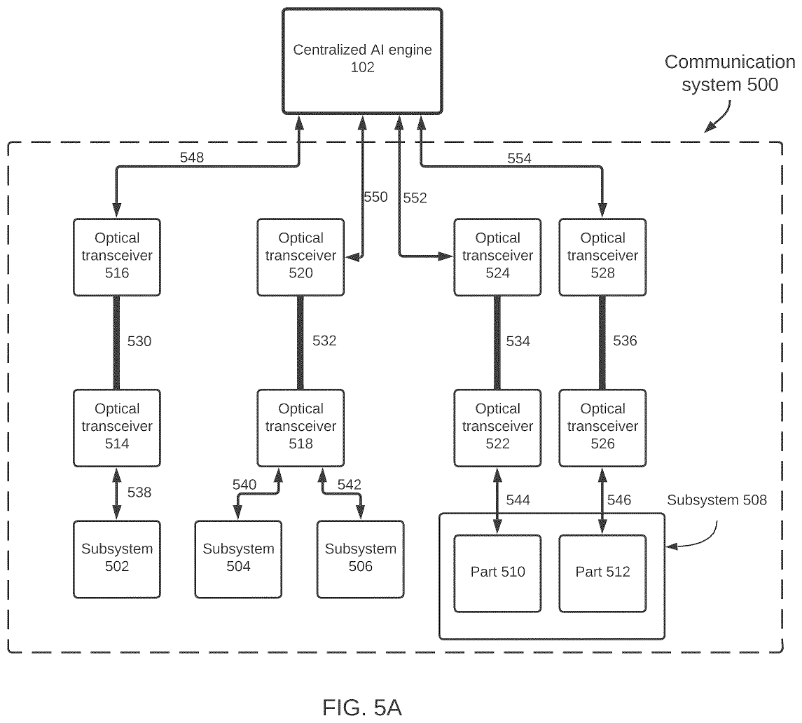

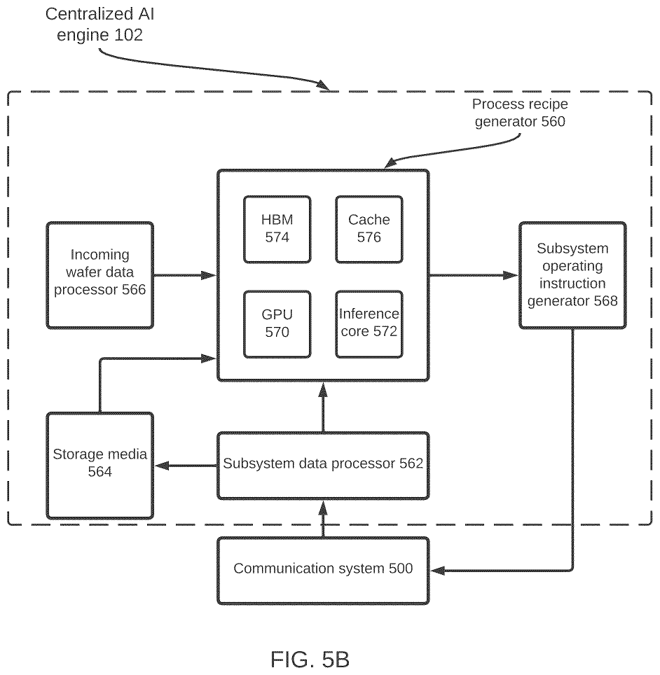

FIG. 5A illustrates a communication system 500 that facilitates connectivity between the centralized AI engine and various subsystems (502, 504, 506, 508), including the parts (510, 512) of the subsystem 508, via optical communication links. This system employs optical fibers, with one implementation showing subsystem 502 linked to the centralized AI engine through a dedicated optical fiber link 530, and optical transceivers 514 and 516 converting signals with assistance of local buses (538, 548). The optical system advantages include high bandwidth, low signal degradation, electromagnetic interference immunity, and compactness compared to electrical cabling, significantly reducing complexity in process chambers inundated with electrical cables. Another implementation has subsystems 504 and 506 sharing optical transceivers 518 and 520 connected by an optical fiber 532, with local data buses (540, 542, 550) facilitating connections to the transceivers.

Further detailing, parts 510 and 512 of subsystem 508 are directly connected to the centralized AI engine 102 via transceivers 522, 524, 526, and 528, utilizing optical fibers 534 and 536, showcasing the system's versatility and the potential for extensive component interconnectivity. Local buses 544, 546, 552, and 554 are used to couple the parts to the transceivers. Notably, essential optical system components, such as light sources and modulation modules (e.g., DWDM and CWDM), are implied for bandwidth enhancement.

FIG. 5B delineates a functional block diagram of the centralized AI engine 102, emphasizing its capacity for autonomous process recipe generation. A process recipe generator 560, equipped with a GPU 570, leverages parallel processing for efficient AI engine operations. An inference core 572, sourcing data from HBM 574, utilizes a trained neural network for recipe formulation, supported by a cache 576 for swift data access. This setup underscores the integration of advanced packaging technologies and the importance of real-time subsystem state data in optimizing process performance. The process recipe generator 560 also incorporates incoming wafer data, reflecting structural, material, and process specifications, potentially sourced from a memory device attached to a standard mechanical interface (SMIF) pod or centralized databases, to tailor the process recipe precisely to the wafer's characteristics. An incoming data processor 566 is used to pre-process the received data for the consumption by the process recipe generator 560. After recipe generation, a subsystem operating instruction generator 568 organizes and dispatches the instructions to the subsystems through the communication system 500, ensuring a seamless and optimized process flow. The centralized AI engine 102 can receive subsystem data feeding from the communication system 500 and process the data by subsystem data processor 562. The processed data can be stored in a storage media 564 and feed into the process recipe generator 560. Real-time subsystem data is severed as an important data source for real-time recipe adjustment by the process recipe generator 560.

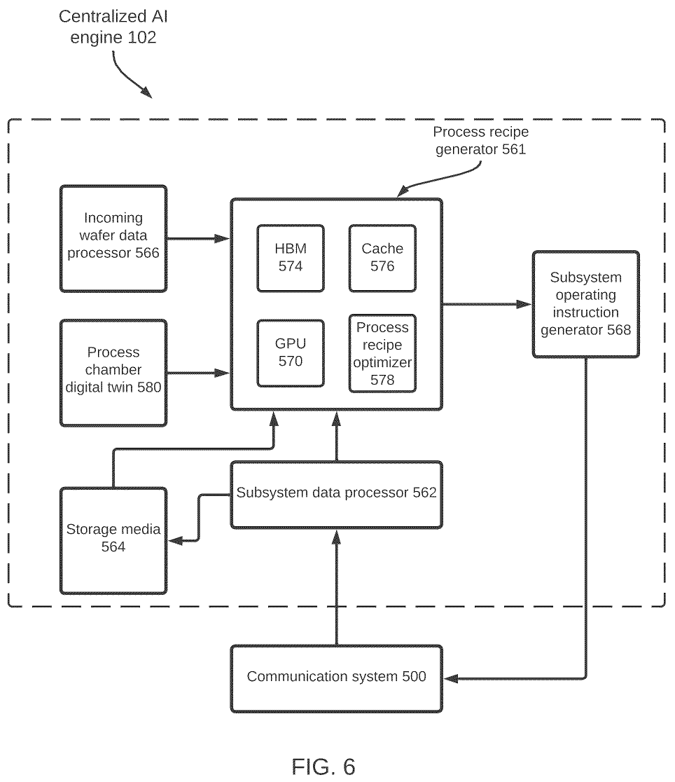

FIG. 6 introduces an alternative design for the centralized AI engine 102, where the emphasis shifts from employing an inference core 572 to using a process recipe optimizer 578. This modification capitalizes on a process chamber digital twin 580, which supplies simulation data to facilitate the optimization of the process recipe. The digital twin encompasses both subsystem digital replicas and a comprehensive chamber process simulation, offering a virtual counterpart to the physical operations of the process chamber. This digital twin can manifest in two primary forms: one grounded in multi-physics models that demand substantial computational resources for precise process simulation within the chamber, and another that relies on more computationally efficient methodologies, including but not limited to neural networks, lookup tables, and analytical models. Specifically, neural networks might be deployed both for subsystem simulations and for emulating the chamber processes, with training potentially based on synthetic data derived from the multi-physics models.

The optimization approach may incorporate various algorithms, such as gradient descent, stochastic gradient descent, and mini-batch gradient descent, or even a Monte Carlo decision tree method, to derive an optimized process recipe based on the digital twins. Part of this optimization involves the development of a loss function designed for minimization. Additionally, the training of neural networks could be further refined using actual measurement data, which, in some cases, may have a more significant influence on the training process.

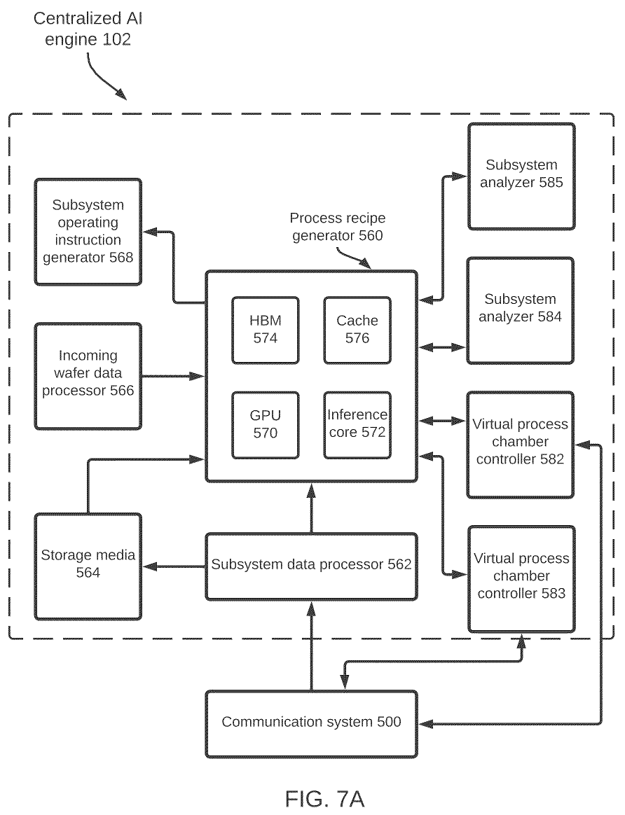

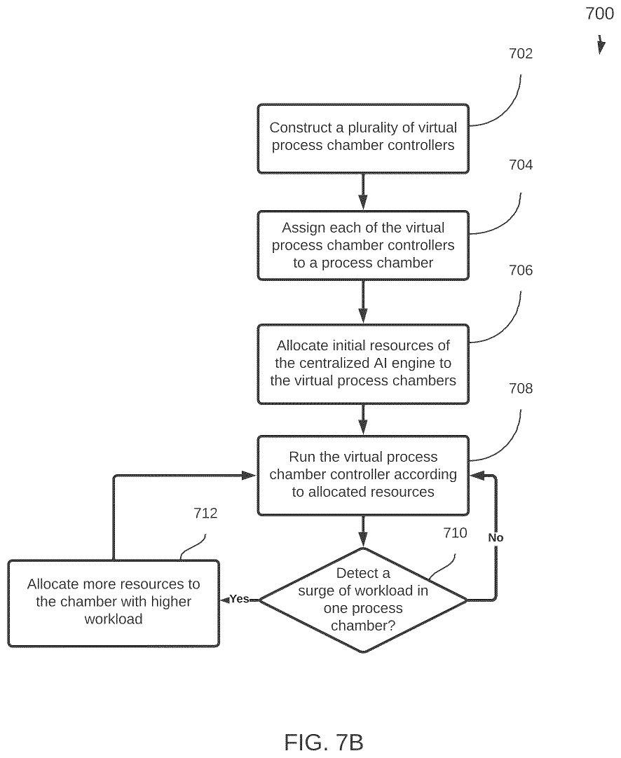

FIG. 7A showcases another embodiment of the centralized AI engine 102, employing a virtualization strategy to create virtual process chamber controllers, such as 582 and 583, as examples. This setup allows each process chamber within the system 100 to be associated with a specific virtual controller, facilitating operations as if each chamber had its dedicated controller. Meanwhile, the centralized AI engine 102 dynamically allocates resources based on the real-time workload distribution among the process chambers, enhancing resource utilization efficiency. For instance, a process chamber requiring more intensive management due to sensor-reported data deviations might receive additional computational resources or even a newly optimized process recipe from the centralized AI engine, enabling adaptive performance improvements in response to subsystem state changes.

A key advantage of this centralized approach is the facilitation of subsystem or part type management, addressing the challenge of process chamber matching in semiconductor manufacturing. Variabilities among subsystems and identical part types can lead to discrepancies in wafer processing performance across chambers. Real-time data analysis from these subsystems and components offers a significant opportunity to enhance process chamber matching. As illustrated in FIG. 7A, subsystem analyzers like 584 and 585 utilize statistical process control (SPC) techniques to examine the data for trends or outliers, leveraging this information to achieve superior process consistency.

FIG. 7B outlines a process for dynamically allocating resources within this centralized AI engine. The process, numbered 700, commences with constructing multiple virtual process chamber controllers (step 702) and assigning each controller to a respective process chamber (step 704). Resources from the centralized AI engine are then allocated based on the projected workload for each chamber (step 706), with the operations of the chambers tailored to the resources dedicated to their corresponding virtual controllers. Should a sudden increase in workload for a particular chamber be detected (step 710), additional resources are promptly allocated to its virtual controller, ensuring optimal chamber performance and efficiency. In one implementation, a portion of the resource maybe reserved for increased demand of resource at a specific time for a specific process chamber. In another implementation, initially allocated resources to the chambers may be reallocated to optimize overall performance of the process systems.

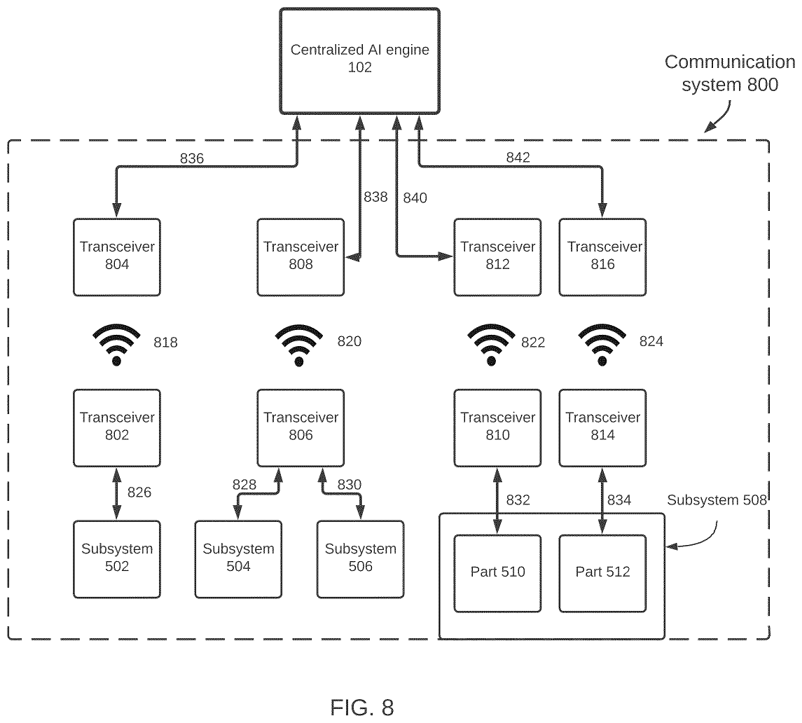

FIG. 8 introduces an embodiment of a communication system, labeled as 800, showcasing various implementations of wireless communication between subsystems and the centralized AI engine 102. In one scenario, subsystem 502 is linked to the centralized AI engine through a dedicated wireless communication link 818, facilitated by transceivers 802 and 804. Local data buses 826 and 836 are employed to connect the subsystem 502 and the centralized AI engine 102 to the transceivers, respectively. This setup supports a range of wireless communication protocols, such as Wi-Fi (IEEE 802.11x), WiMax (IEEE 802.16), LTE, 5G, 5.5G and the forthcoming 6G, offering flexibility and scalability in communication. Another configuration allows two subsystems, 504 and 506, to share a single wireless link 820, with paired transceivers 806 and 808 with assistance from local data buses (828, 830, and 838) to manage the connectivity. A further arrangement connects parts 510 and 512 of subsystem 508 directly to the centralized AI engine via individual wireless links 822 and 824, utilizing transceivers 810, 812, 814, and 816, with local data buses (832, 834, 840, and 842) ensuring seamless communication.

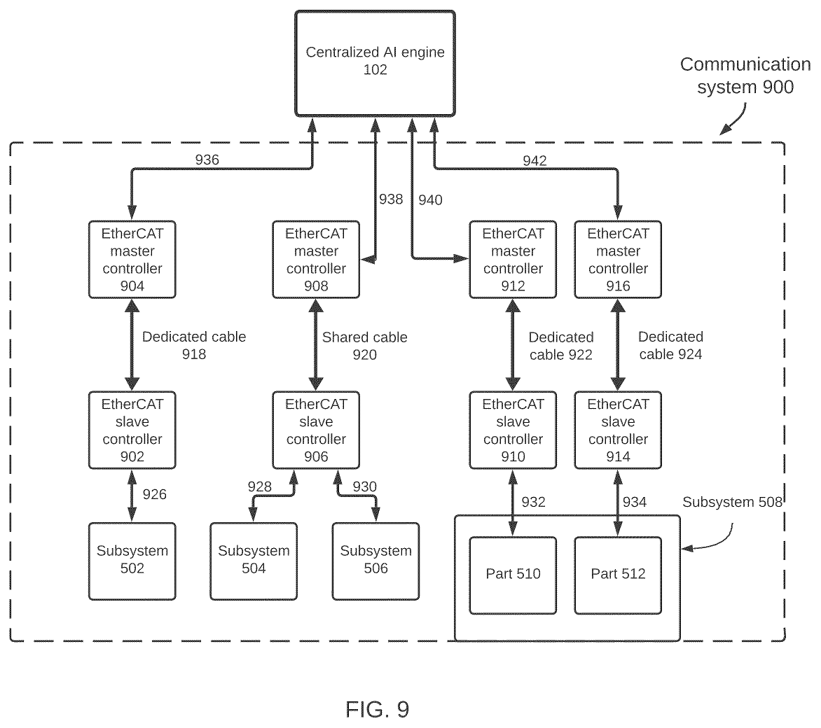

FIG. 9 depicts another communication system variant, marked as 900, where EtherCAT technology underpins the connectivity. One implementation connects subsystem 502 to the AI engine with an EtherCAT cable 918, employing an EtherCAT slave controller 902 and master controller 904, with local data buses 926 and 936 optionally facilitating the connection. Another setup sees subsystems 504 and 506 sharing an EtherCAT link via cable 920, linked to EtherCAT controllers 906 and 908 at respective ends. Local data buses (928, 930, 938) are used to connect the subsystems (504, 506) and the centralized AI engine (102) to the controllers (906, 908), respectively. Additionally, parts 510 and 512 of subsystem 508 are individually connected through EtherCAT cables 922 and 924, supported by controller pairs 910/912 and 914/916 with assistance of local data buses (932, 934, 940, 942), respectively, highlighting EtherCAT's adaptability for precise and efficient industrial communication.

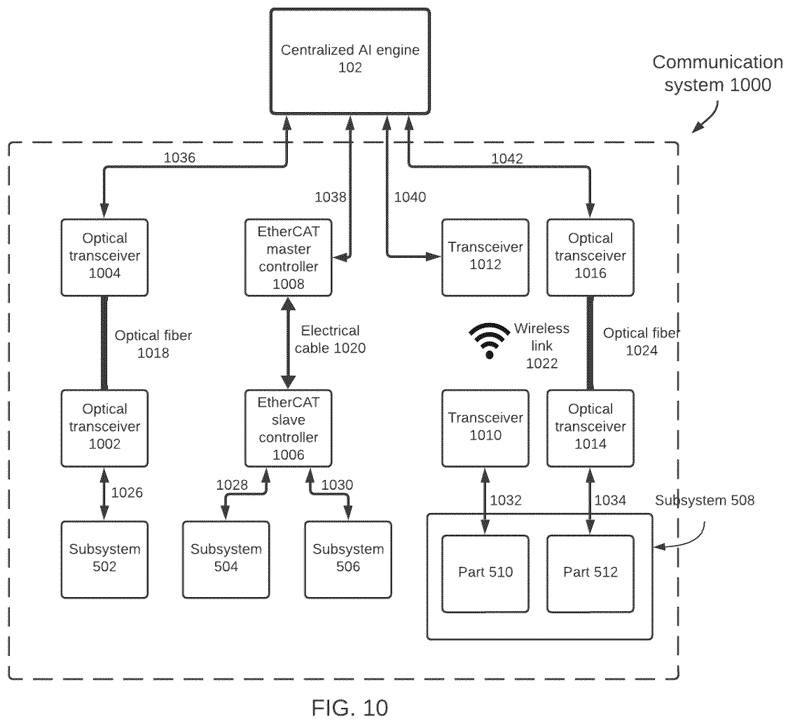

FIG. 10 outlines a comprehensive communication system, identified as 1000, integrating diverse communication technologies. Subsystem 502 connects to the AI engine 102 via an optical link, employing transceivers 1002/1004, optical fiber 1018, and local data buses 1028 and 1036. Subsystems 502 and 504 utilize a shared EtherCAT link with cable 1020 and controllers 1006/1008, supplemented by local buses (1028, 1030, 1038). A wireless link, through transceivers 1010/1012, connects part 510 of subsystem 508, whereas an optical link with fiber 1024 and transceivers 1014/1016 connects part 512, demonstrating a hybrid approach that leverages the strengths of various communication methods to ensure optimal connectivity and performance. Local buses (1032, 1034, 1040, 1042) are employed to facilitate the local connections.

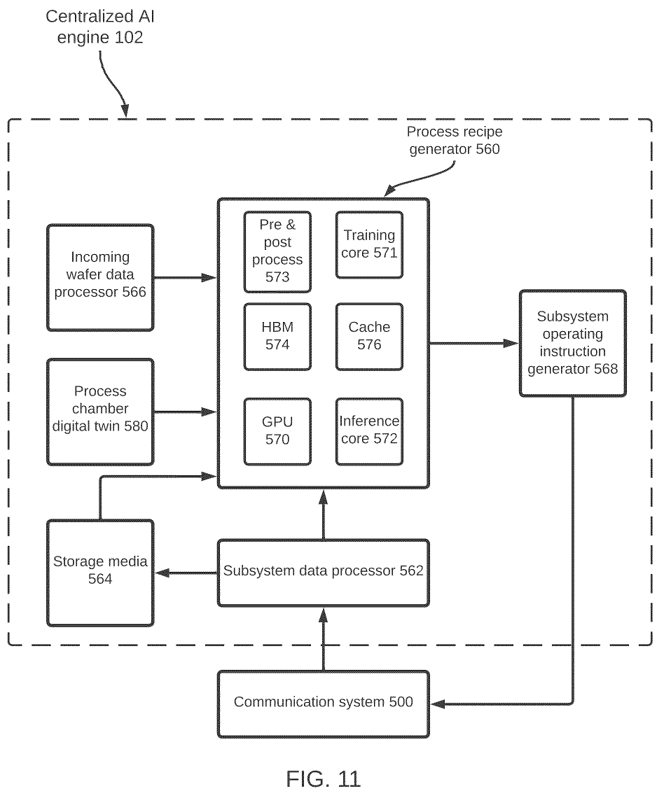

FIG. 11 unveils an enhanced version of the centralized AI engine 102, incorporating a training core 571 and a pre-and post-process unit 573. This setup enables the centralized AI engine 102 to train neural networks, which are pivotal for operations like constructing efficient digital twins or generating process recipes based on subsystem states and incoming wafer data. In one implementation, the training core 571 facilitates the use of synthetic data from multi-physics models for training the networks as parts of the computational efficient digital twin for the process chamber. The pre-processing unit prepares data templates, and the post-processing unit standardizes output formats for broader applicability. In another implementation, the training core 571 is utilized to train the neural network used for the inference core 572. This flexibility allows for the centralized AI engine 102 to be versatile in its application, accommodating both internal and cloud-based training, and highlights the potential for multiple AI engines to pool resources, especially for computationally intensive tasks like training, enhancing the scalability and efficiency of AI applications in industrial settings.

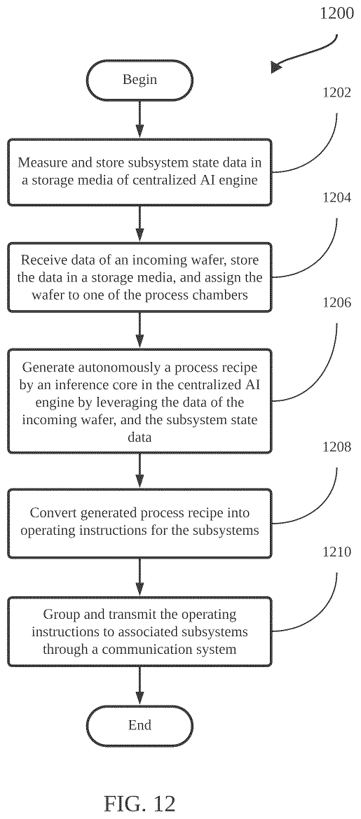

FIG. 12 presents a flowchart that details the steps for autonomously generating a process recipe, a crucial component for optimizing semiconductor manufacturing processes. The procedure, designated as process 1200, begins with step 1202, where subsystem state data is collected and preserved within a storage media 564, potentially integrated as part of HBM 574. Following this, step 1204 involves the centralized AI engine 102 receiving data pertinent to an incoming wafer scheduled for processing. This data may be archived either in the storage media 564 or directly within HBM 574, or it might be immediately processed by the centralized AI engine 102 to formulate a process recipe. A critical prerequisite for recipe generation, occurring before step 1206, is the assignment of a suitable process chamber to the wafer, given that the state data for each chamber could influence the recipe's specifics. The recipe itself is autonomously crafted in step 1206, leveraging the inference core 572, which utilizes both subsystem state data and incoming wafer data. The operation of the inference core 572, which may entail extensive matrix computations, significantly benefits from the parallel processing capabilities of GPUs. In step 1208, the newly generated process recipe is translated into operational instructions for the subsystems, which are then organized and dispatched to the corresponding subsystems through the communication system 500 in step 1210.

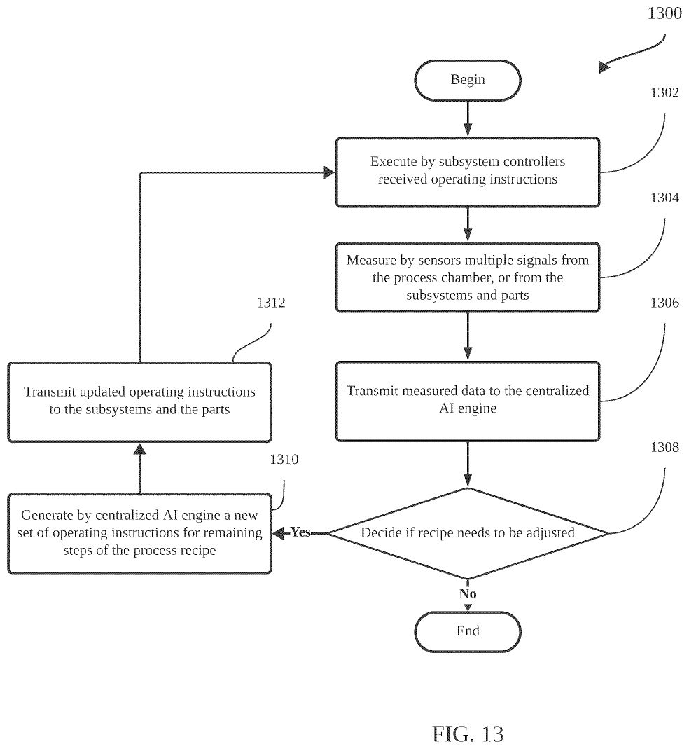

FIG. 13 outlines a procedure, encapsulated in process 1300, for dynamically adjusting a process recipe in real-time during an ongoing processing event. This process initiates with step 1302, where subsystem operating instructions are executed as per their scheduled time steps. During the event, as denoted in step 1304, various sensors within the process chamber and across different subsystems and parts collect multiple signals. The gathered data are then relayed to the centralized AI engine 102 via the communication system 500 in step 1306. Step 1308 involves the centralized AI engine 102 analyzing the received data to determine if adjustments to the process recipe are necessary for the subsequent steps of the process. If modifications are deemed essential, a fresh set of operating instructions for remaining steps of the process recipe are created in step 1310 and subsequently transmitted to the subsystems in step 1312, ensuring the process adapts to real-time conditions and data.

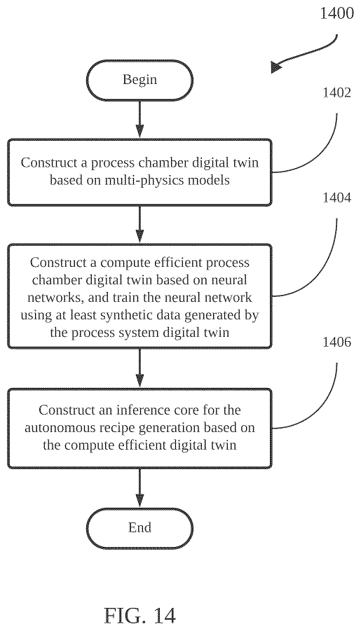

FIG. 14 depicts the methodology behind creating a computationally efficient digital twin and an inference core based on the digital twin, as detailed in process 1400. Starting with step 1402, a digital twin of the process chamber is developed using multi-physics models to simulate on-wafer results by executing the process recipe virtually. Step 1404 sees the construction of a more computationally efficient digital twin through the application of various neural networks, trained using synthetic data from the multi-physics models, with real measurement data potentially augmenting this training. Finally, in step 1406, another neural network is trained to serve as the inference core 572, utilizing synthetic data from the digital twin and taking into account incoming wafer data and subsystem state data to autonomously generate process recipes.

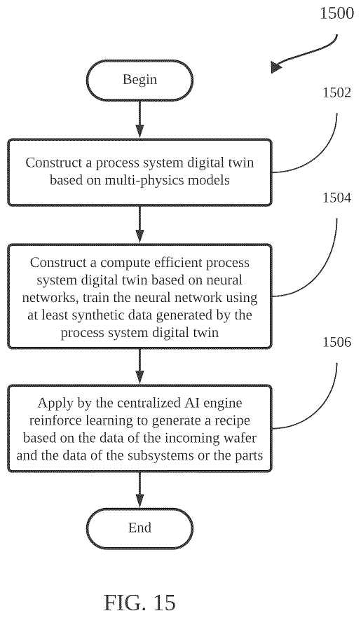

FIG. 15 introduces an alternative methodology for autonomously generating a process recipe, delineated in process 1500. Similarly to process 1400, it begins with the creation of a digital twin based on multi-physics models in step 1502, followed by the development of a computationally efficient digital twin using neural networks in step 1504. In step 1506, an optimization procedure is applied to devise the process recipe, utilizing the digital twin, and constructing a loss function to meet desired output performance criteria. This step might incorporate various optimization algorithms or adopt a reinforcement learning approach to establish a policy for selecting actions during specific steps of the process, ensuring the recipe is optimized for efficiency and effectiveness.

1. A process system, comprising:
a plurality of process chambers, each comprising a plurality of subsystems, which in turn includes a plurality of parts;
a centralized AI engine tasked with controlling operations of the said process chambers, wherein the centralized AI engine is directly interfaced with either the subsystems or the parts;
an autonomous process recipe generator, delineated as a key functionality within the centralized AI engine, designed to autonomously craft process recipes; and
a communication system established to facilitate the linkage of the subsystems or parts with the centralized AI engine, enabling the subsystems or the parts to directly receive operational instructions dispatched from the centralized AI engine.

2. The process system as recited in claim 1, wherein the autonomous process recipe generator is equipped with an inference core, which utilizes a trained neural network for the generation of process recipes.

3. The process system as recited in claim 1, wherein the centralized AI engine comprises a plurality of HBMs, GPUs, and caches to facilitate efficient data processing and storage.

4. The process system as recited in claim 1, wherein the centralized AI engine includes a training core that receives at least synthetic data produced by a process chamber digital twin for the purpose of neural network training.

5. The process system as recited in claim 1, wherein the process chamber digital twin encompasses digital replicas of the subsystems and simulates processes executed within the process chamber.

6. The process system as recited in claim 1, wherein the process chamber digital twin employs multi-physics models to simulate physical and chemical phenomena within the chamber.

7. The process system as recited in claim 6, wherein the process chamber digital twin can be optimized into a compute-efficient digital twin utilizing neural networks trained with synthetic data derived from multi-physics models.

8. The process system as recited in claim 1, wherein the subsystems are equipped with controllers that convert received operating instructions from the centralized AI engine into time series control signals for the subsystems' parts.

9. The process system as recited in claim 1, wherein the communication system incorporates optical communication links to facilitates data transfer between the subsystems or parts and the centralized AI engine.

10. The process system as recited in claim 1, wherein the communication system includes wireless communication links supporting protocols Wi-Fi, LTE, 5G, 5.5G, or 6G.

11. The process system as recited in claim 1, wherein the communication system utilizes dedicated or shared EtherCAT communication links for data exchange.

12. The process system as recited in claim 1, wherein the centralized AI engine is configured with a plurality of virtual controllers, each assigned to a respective process chamber for tailored operations and controls.

13. The process system as recited in claim 12, wherein resources of the centralized AI engine are allocated to each of the plurality of the virtual controllers according to its workload in real-time.

14. The process system as recited in claim 1, wherein the centralized AI engine integrates one or a plurality of subsystem analyzers for assessing the performance across multiple instances of identical subsystem types.

15. The process system as recited in claim 14, wherein the subsystem analyzers are designed to evaluate trends in subsystem parameters, identifying deviations and outliers to maintain optimal performance.

16. A method for generating process recipes in a process system, comprising the steps of:
measuring and storing a first set of data that describes the states of a plurality of subsystems within a storage media of a centralized AI engine, wherein said subsystems are directly coupled to said centralized AI engine through communication links of a communication system;
receiving by said centralized AI engine a second set of data describing an incoming wafer and storing said second set of the data in said storage media;
assigning one process chamber from the plurality of process chambers for processing of said incoming wafer;
autonomously generating a process recipe by said centralized AI engine, wherein a portion of the first set of the data related to the assigned chamber and the second set of data are taken as inputs of an inference core as a part of said centralized AI engine;
converting the generated process recipe into operating instructions by said centralized AI engine for the subsystems of the assigned chamber; and
transmitting said operating instructions to the subsystems through the communication links directly coupling to said centralized AI engine and the subsystems.

17. The method as recited in claim 16, further including adjusting the recipe during a process event based on real-time measurement of a plurality of parameters associated with the assigned process chamber or its subsystems.

18. The method as recited in claim 16, wherein said inference core is trained by at least synthetic data generated by a process chamber digital twin.

19. The method as recited in claim 16, further including receiving said operating instructions by subsystem controllers, wherein said subsystem controllers convert the operating instructions into time series control signals and distribute the control signals to subsystem parts according to a starting time adjusting scheme which minimizes latency of the subsystems.

20. The method as recited in claim 16, where said process chamber digital twin is generated based on multi-physics models and said process chamber digital twin is further simplified into a computationally efficient process chamber digital twin based on neural networks.
